(19) United States
(12) Patent Application Publication
(10) Pub. No.: US 2009/0142489 A1
(43) Pub. Date: Jun. 4, 2009

(54) LINEAR DEPOSITION SOURCES FOR DEPOSITION PROCESSES

(75) Inventors: Tai Joon Um, Seoul (KR); Young Cheol Joo, Chungcheongnam (KR); Sang Wook Lee, Gyeonggi-do (KR); Kug Weon Kim, Seoul (KR)

Correspondence Address: KNOBBE MARTENS OLSON & BEAR LLP, 2040 MAIN STREET, FOURTEENTH FLOOR, IRVINE, CA, 92614, US

(73) Assignee: SOONCHUNHYANG UNIVERSITY INDUSTRY ACADEMY COOPERATION FOUNDATION, Chungcheongnam-do (KR)

(21) Appl. No.: 12/295,696

(22) PCT Filed: Jul. 30, 2007
(86) PCT No.: PCT/KR07/03654

§ 371 Date: Jan. 15, 2009

(30) Foreign Application Priority Data
Aug. 4, 2006 (KR) 10-2006-0073590
Jul. 5, 2007 (KR) 10-2007-0067497

(51) Int. Cl. C23C 16/02

(52) U.S. Cl. 427/248.1; 118/692; 118/724

(57) ABSTRACT

Linear deposition sources are disclosed. In one embodiment, the linear deposition source includes a container accommodating evaporation material and a heater configured to generate heat energy such that vaporized material is discharged uniformly onto a substrate on which a deposition layer is formed. The heater is provided on the container, wherein a portion of the heater positioned at a center portion of the container in the longitudinal direction generates more heat energy than the other portion of the heater. The heater includes a coil configured in a sinusoidal pattern, wherein the curvature pitch or height of the portion of the coil positioned at the center portion of the container in the longitudinal direction is set to be different from that of the other portion of the coil. Further, the resistance of the portion of the coil positioned at the center portion of the container in the longitudinal direction may be set to be greater than that of the other portion of the coil.

### TECHNICAL FIELD

The present disclosure relates generally to deposition processes, and more particularly to linear deposition sources for use in deposition processes.

### BACKGROUND

Thermal physical vapor deposition (PVD) processes have been used widely in forming thin films made of various materials. For example, PVD processes are commonly used for forming organic thin films and metal electrode layers in organic light emitting diodes (OLEDs). In this process, an organic material is heated to a point of vaporization (or sublimation) and the vaporized organic material is coated on a substrate after the vaporized organic material is discharged out of the deposition source.

Conventional PVD processes typically employ a vapor deposition device which includes a crucible having high heat resistance and chemical stability in an evaporation chamber. FIG. 1 illustrates a longitudinal cross-sectional view of a conventional linear deposition source 100, which includes an electrically insulated container 110 for containing an evaporation material 150. The container 110 has side walls 114 formed in a longitudinal direction, end walls (not shown) connecting the side walls 114, and a bottom wall 118. Around the side walls 114 and end walls, a heater 112 including a coil is provided to generate heat energy for vaporizing the evaporation material 150 in the container 110. In addition, the linear deposition source 100 includes a top plate 120 for sealing the container 110 and a housing 130 for receiving the container 110 and the heater 112. A plurality of nozzles 122 are provided in the top plate 120 to permit evaporation materials to pass through onto a surface of a deposition target (not illustrated).

As shown, the container 110 is filled with an evaporation material 150 such as an organic material in a solid or powder form. The heater 112 including the coil is configured to generate heat energy in response to an electrical current supplied from an external current source (not shown). The heat energy generated from the heater 112 is then transferred to the evaporation material 150 through the walls of the container 110, such that the evaporation material 150 vaporized by the heat energy is discharged through the nozzles 122 to be deposited on a deposition target positioned above the linear deposition source 100.

When manufacturing an OLED, a metal layer and an organic layer such as a charge transport layer and a charge injection layer are formed using PVD processing. Because an organic layer is a very thin film, any variation in the film thickness may have an adverse effect in the emissive brightness and color of an OLED. Further, because an organic layer is formed between an anode and a cathode, any variation in the thickness of the organic layer may cause a short circuit between the anode and the cathode, thereby leading to a display defect.

Unfortunately, as the display area of an OLED becomes larger, conventional deposition sources may not provide sufficient uniformity for large deposition areas. For example, when a single-point type deposition source is used for depositing organic material onto a large area, there may be significant variances in the distance between the deposition source to different sections of the deposition target substrate to an extent that may result in non-uniformity of deposition thickness. Further, even when the linear deposition source of FIG. 1 is used for depositing organic material, due to the non-uniformity of heat energy in the container 110, the evaporation material is not vaporized in a uniform manner, and thus is not discharged uniformly from the linear deposition source. Particularly, the configuration of the heater 112 surrounding the container 110 typically causes the organic material 150 located near the end walls to be vaporized more readily than the material 150 located near the center portion of the side walls 114 along the longitudinal direction. As a result of such non-uniformity, the deposition layer formed on a deposition target may not be of uniform thickness.

### SUMMARY

The present disclosure is directed to linear deposition sources for use in deposition processes that include a heater configured to provide substantially uniform heat energy to deposition materials in the linear deposition source. The heater configuration of the present disclosure allows vaporization of deposition materials in a more uniform manner and thus provides a more uniform discharge of the deposition materials onto a substrate to form a more uniform deposition layer.

In one embodiment, a linear deposition source for use in a thermal physical vapor deposition process includes a container, a top plate, and a heater. The container is configured to receive one or more evaporation materials and includes a pair of side walls formed in a longitudinal direction of the container, a pair of end walls, and a bottom wall. The top plate is configured to seal an opening of the container and includes one or more outlets for discharging the evaporation material. The heater is disposed around the side walls and end walls of the container such that a first portion of the heater extending a first distance in the longitudinal direction along a center portion of the side walls generates more heat energy than a second portion of the heater extending the first distance in the longitudinal direction along an outer portion of the side walls.

In another embodiment, a linear deposition source for use in a thermal physical vapor deposition process includes a container and a heater. The container includes at least one wall to define a chamber and is configured to receive an evaporation material. The heater is disposed around the wall of the container such that a first portion of the heater extending a first distance in the longitudinal direction along a center portion of the wall generates more heat energy than a second portion of the heater extending the first distance in the longitudinal direction along an outer portion of the wall.

In another embodiment, a linear deposition source for use in a thermal physical vapor deposition process includes a container and a heater. The container includes at least one wall to define a chamber and is configured to receive an evaporation material. The heater includes a coil disposed around the wall of the container such that a first portion of the coil extending a first distance in the longitudinal direction along a center portion of the wall generates more heat energy than a second portion of the coil extending the first distance in the longitudinal direction along an outer portion of the wall.

In yet another embodiment, a linear deposition source for use in a thermal physical vapor deposition process includes a container, a plate, and a heater coil. The container is configured to receive one or more evaporation materials and includes a pair of side walls formed in a longitudinal direction of the container. The plate is configured to seal an opening of the container and includes one or more nozzles for discharging the evaporation material. The heater coil is disposed around the side walls, wherein a first portion of the heater coil extending a first distance in the longitudinal direction along a center portion of the side walls generates more heat energy than a second portion of the heater coil extending the first distance in the longitudinal direction along an outer portion of the side walls.

### BRIEF DESCRIPTION OF THE DRAWINGS

FIG. 1 shows a cross-sectional view of a conventional linear deposition source used in physical vapor deposition processing.

FIG. 2 illustrates a perspective view of a linear deposition source for use in a thermal physical vapor deposition process in accordance with one embodiment of the present disclosure.

FIG. 3 illustrates a perspective view of a linear deposition source for use in a thermal physical vapor deposition process in accordance with another embodiment of the present disclosure.

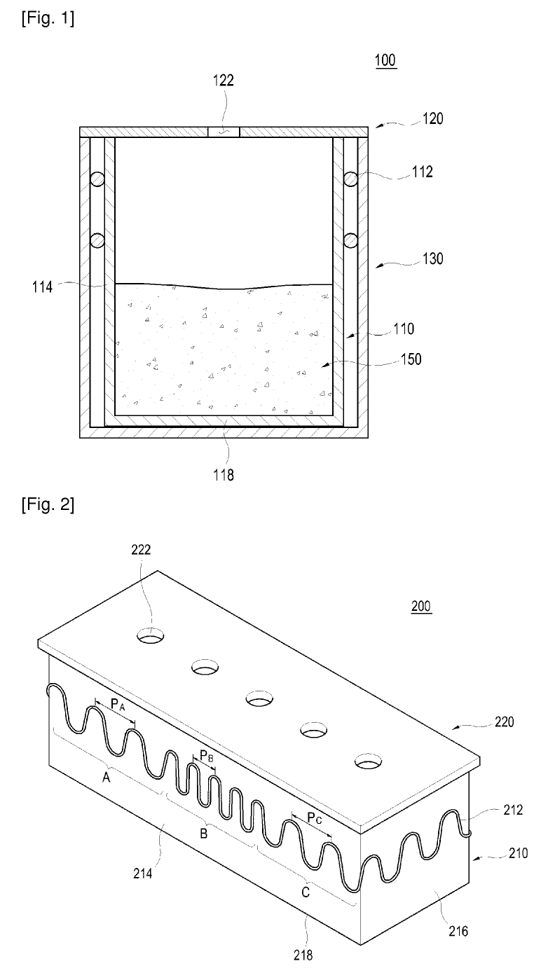

### DETAILED DESCRIPTION

In the following description, numerous specific details are set forth. It will be apparent, however, that these embodiments may be practiced without some or all of these specific details. In other instances, well known process steps or elements have not been described in detail in order not to unnecessarily obscure the disclosure.

The present disclosure describes linear deposition sources for use in PVD or other suitable deposition processes. For example, in several applications the linear deposition sources can be used in PVD processes for manufacturing a display device such as an OLED. The linear deposition source of the present disclosure includes a heater configured to provide substantially uniform heat energy to deposition materials in the linear deposition source. The heater configuration allows vaporization of deposition materials in a more uniform manner and thus provides a more uniform discharge of the deposition materials onto a substrate to form a more uniform deposition layer.

In one embodiment, the linear deposition source includes a container defining a chamber for receiving evaporation material. The linear deposition source further includes a heater surrounding the container, wherein a portion of the heater positioned at a center portion of the container in the longitudinal direction generates more heat energy than other portion of the heater. In another embodiment, the container has a pair of side walls formed in a longitudinal direction of the container, a pair of end walls, and a bottom wall, wherein the heater disposed around the side walls and end walls of the container. In such case, the container defines a volume having three substantially equal sections, one of the sections being adjacent to a center portion of the side walls and the other sections being adjacent to the end walls, wherein the heater is configured to provide approximately same heat energy to each of the sections.

The heater may include a coil arranged in geometric pattern such as a zigzag and/or sinusoidal pattern, or any variation of such pattern. In one embodiment, a curvature pitch of the portion of the coil positioned at a center portion of the container in the longitudinal direction is smaller than that of the other portion of the coil. In another embodiment, a curvature height of the portion of the coil positioned at a center portion of the container in the longitudinal direction is higher than that of the other portion of the coil. Alternately, a resistance of the portion of the coil positioned at a center portion of the container in the longitudinal direction may be set to be greater than that of the other portion of the coil.

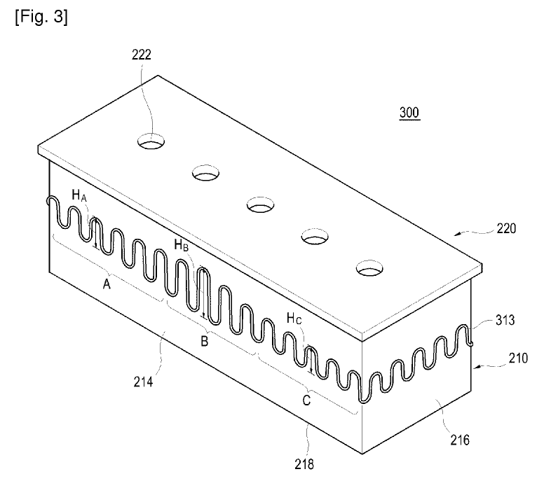

FIG. 2 illustrates a linear deposition source 200 for use in a PVD process in accordance with one embodiment of the present disclosure. The linear deposition source 200 includes a container (e.g., crucible, chamber, etc.) 210 defining a chamber that is arranged to receive an evaporation material (e.g., organic material) and is constructed of electrically insulating materials such as quartz and ceramic material. The container 210 includes a pair of side walls 214 formed in a longitudinal direction of the container 210, a pair of end walls 216 connecting the side walls 214, a bottom wall 218, and a top plate 220. The top plate 220 is arranged to seal the container 210 and includes a plurality of outlets 222 configured to permit vaporized evaporation material to pass through and onto a surface of a substrate (not illustrated). Around the container 210, the linear deposition source 200 also includes a heater 212 having a coil configured in a sinusoidal or zigzag pattern, or any suitable variations of such pattern.

The container 210 is configured to be filled with one or more evaporation materials such as organic materials in a solid or powder form. The coil of the heater 212 is configured to generate heat energy in response to an electrical current supplied from an external current source (not illustrated). The heat energy generated by the coil of the heater 212 varies depending on the resistivity of the coil. In one embodiment, the coil of the heater 212 may have a resistivity of about 2.2×10⁻⁷ Ω□m. Further, the coil of the heater may be made of any metallic material having high melting point such as tantalum, tungsten and molybdenum, etc., which is configured to have a constant section area (i.e., constant resistance) in its longitudinal direction.

The heat energy generated from the heater 212 is transferred to the evaporation material in the container 210 through the walls of the container 210 such that the evaporation material is vaporized. The vaporized material is then discharged through the outlets 222 to be deposited on a substrate positioned above or otherwise adjacent to the linear deposition source 200.

In the linear deposition source 200 as shown in FIG. 2, the curvature pitch of the coil 212 is set to be different depending on its position on the side walls and end walls of the container 210. For example, a curvature pitch P_{B} of a portion B of the coil 212 positioned on a center portion of the side wall 214 of the container 210 is set to be smaller than curvature pitches P_{A} and P_{C} of the other portions A and C of the coil 212.

Accordingly, the heat energy radiated from a portion of the coil 212 positioned on the center portion B of the side wall 214 is greater than the heat energy radiated from the other portions A and C of the coil 212 with respect to a unit area of the side walls 214 of the container 210. In this configuration, the rate of the curvature pitch P_{B} of the portion B of the coil 212 to the curvature pitches of the other portions (including the portions A and C at the side walls and the portions at the end walls) of the coil 212 can be adjusted such that the coil 212 as a whole provides substantially uniform heat energy or evaporation rate to the material in the container 210 along the longitudinal direction. Thus, the evaporation rate near the center portion of the side walls 214 of the container 210 substantially matches the evaporation rate near the end walls 216 of the container 210. Due to more uniform evaporation rate in the container 210, the vaporized material is discharged in a more uniform manner through the outlets 222 arranged along the top plate 220 of the linear deposition source 200.

FIG. 3 illustrates a linear deposition source 300 for use in a PVD process in accordance with another embodiment of the present disclosure. The linear deposition source 300 has the same configuration as the linear deposition source 200 as shown in FIG. 2 except that a heater 313 has a different configuration from the heater 212 in FIG. 2. Thus, each component of the linear deposition source 300 in FIG. 3, having substantially the same function as the counterpart shown in FIG. 2, is identified by the same reference numeral and the description thereof will be omitted herein.

As shown in FIG. 3, the linear deposition source 300 includes a heater 313 having a coil configured in a sinusoidal or zigzag pattern to provide more uniform heat energy in a longitudinal direction of the container 210. In this arrangement, the coil of the heater 313 may be made of any metallic material having a high melting point such as tantalum, tungsten and molybdenum, etc. In one embodiment, the coil of the heater 313 is configured to have a resistivity of about 2.2×10⁻⁷ Ω□m and have constant resistance in its longitudinal direction.

In the linear deposition source 300, the curvature height of the coil 313 is set to be different depending on its position around the side walls and end walls of the container 210. For example, a curvature height H_{B} of a portion B of the coil 313 positioned on a center portion of the side wall 214 of the container 210 is set to be higher than curvature heights H_{A} and H_{C} of the other portions A and C of the coil 313. Accordingly, the heat energy radiated from a portion of the coil 313 positioned on the center portion B of the side wall 214 is greater than the heat energy radiated from the other portions A and C of the coil 313 with respect to a unit area of the side wall 214 of the container 210. In this configuration, the ratio of the height H_{B} of the portion B of the coil 313 to the heights of the other portions (including the portions A and C at the side walls and the portions at the end walls) of the coil 313 can be adjusted such that the coil 313 as a whole provides substantially uniform heat energy or evaporation rate to the material in the container 210 in the longitudinal direction. Thus, the evaporation rate near the center portion of the side walls 214 of the container 210 substantially matches the evaporation rate near the end walls 216 of the container 210. Due to more uniform evaporation rate in the container 210, the vaporized material is discharged in a more uniform manner through the outlets 222 arranged along the top plate 220 of the linear deposition source 300.

For ease of explanation, a housing for accommodating the container and the heater of the linear deposition source is not illustrated in FIGS. 2 and 3. However, each of the linear deposition sources as shown in FIGS. 2 and 3 may further include a housing for accommodating the container 210 and the heater 212 or 313.

In the embodiments described above, the coils of the heaters 212 and 313 are configured to have constant section area (i.e., resistance) in the longitudinal direction. However, in order to increase heat energy generated from a portion of the coil positioned at a center portion of the side walls 214 of the container 210, the resistance of the portion of the coil positioned at the center portion of the side walls 214 may be set to be greater than the other portion of the coil. Further, the heater coil may be configured in any suitable manner with or without curvatures (e.g., rectangle and polygon shapes).

In FIGS. 2 and 3, while the outlets 212 are shown in the top plate 220 of the linear deposition sources 200 and 300, the outlets may be provided in any suitable walls of the container. Further, although a plurality of outlets 212 for discharging vaporized materials have been described to be arranged in a row on the top plate of the linear deposition source in the above-described embodiments, the outlets 212 can be in any elongated pattern, including multiple rows, staggered or aligned, and they can be apertures of any shape, including a circular, rectangular, elliptical, oval, or square shape. Alternatively, the outlets 212 of the top plate 220 in the linear deposition sources 200 and 300 may be implemented using nozzles, which are configured to control the rate of flow, speed, direction, mass, and/or the pressure of vaporized evaporation material passing therethrough. In addition, the outlets 212 on the top plate of the linear deposition sources 200 and 300 may be configured as a linear slit for discharging vaporized material. The container 210 of the linear deposition sources 200 and 300 may also define a chamber having a cross section of other than rectangular shape such as circular, elliptical and polygonal shapes.

1. A linear deposition source for use in a deposition process, comprising:
a container configured to receive one or more evaporation materials, the container having a pair of side walls formed in a longitudinal direction of the container, a pair of end walls, and a bottom wall;
a top plate configured to seal an opening of the container and having one or more outlets for discharging the evaporation material; and
a heater disposed around the side walls and end walls of the container, wherein a first portion of the heater extending a first distance in the longitudinal direction along a center portion of the side walls, and a second portion of the heater extending the first distance in the longitudinal direction along an outer portion of the side walls, wherein the first portion of the heater is configured to generate more heat energy than the second portion of the heater.

2. The linear deposition source of claim 1, wherein the heater includes a coil configured in a sinusoidal pattern.

3. The linear deposition source of claim 1, wherein the heater includes a coil configured in a zigzag pattern.

4. The linear deposition source of claim 1, wherein the heater includes a coil of a geometric pattern having a pitch and wherein a pitch of a portion of the coil positioned at a center portion of the side walls is smaller than a pitch of the other portion of the coil.

5. The linear deposition source of claim 1, wherein the heater includes a coil of a geometric pattern having a height and wherein a height of a portion of the coil positioned at a center portion of the side walls is greater than a height of the other portion of the coil.

6. The linear deposition source of claim 1, wherein the heater includes a coil and wherein a resistance of a portion of the coil positioned at a center portion of the side walls is greater than a resistance of the other portion of the coil.

7. The linear deposition source of claim 1, wherein the heater includes a coil and wherein the coil is made of metallic material having high melting point and a constant resistance in a longitudinal direction of the coil.

8. The linear deposition source of claim 7, wherein the coil has a resistivity of about 2.2×10⁻⁷ Ωm.

9. The linear deposition source of claim 8, wherein the coil is made of tantalum, tungsten or molybdenum.

10. The linear deposition source of claim 1, wherein the outlets of the top plate include apertures arranged in a row on the top plate.

11. The linear deposition source of claim 1, wherein the outlets of the top plate include apertures configured to control a rate of flow, speed, direction, mass, and/or pressure of the evaporation material.

12. The linear deposition source of claim 1, wherein the outlets of the top plate include a linear slit for discharging the evaporation material.

13. A linear deposition source for use in a vapor deposition process, comprising:
a container defining a chamber and configured to receive an evaporation material, the container having at least one wall formed in a longitudinal direction of the container;
a heater disposed around the wall of the container wherein a first portion of the heater extending a first distance in the longitudinal direction along a center portion of the wall and a second portion of the heater extending the first distance in the longitudinal direction along an outer portion of the wall, wherein the first portion of the heater is configured to generate more heat energy than the second portion of the heater.

14. The linear deposition source of claim 13, wherein the heater includes a coil configured in a sinusoidal pattern.

15. The linear deposition source of claim 13, wherein the heater includes a coil configured in a zigzag pattern.

16. The linear deposition source of claim 13, wherein the heater includes a coil of a geometric pattern having a pitch and wherein a pitch of a portion of the coil positioned at a center portion of the wall is smaller than a pitch of the other portion of the coil.

17. The linear deposition source of claim 13, wherein the heater includes a coil of a geometric pattern having a height and wherein a height of a portion of the coil positioned at a center portion of the wall is greater than a height of the other portion of the coil.

18. The linear deposition source of claim 13, wherein the heater includes a coil and wherein a resistance of a portion of the coil positioned at a center portion of the wall is greater than a resistance of the other portion of the coil.

19. The linear deposition source of claim 13, wherein the heater includes a coil and wherein the coil is made of metallic material having high melting point and a constant resistance in a longitudinal direction of the coil.

20. The linear deposition source of claim 19, wherein the coil has a resistivity of about 2.2×10⁻⁷ Ωm.

21. The linear deposition source of claim 20, wherein the coil is made of tantalum, tungsten or molybdenum.

22. A linear deposition source for use in a vapor deposition process, comprising:
a container defining a chamber and configured to receive an evaporation material the container having at least one wall formed in a longitudinal direction of the container;
a heater including a coil disposed around the wall of the container, wherein a first portion of the coil extending a first distance in the longitudinal direction along a center portion of the wall and a second portion of the coil extending the first distance in the longitudinal direction along an outer portion of the wall, wherein the first portion of the coil has a first length and the second portion of the coil has a second length less than the first length.

23. The linear deposition source of claim 22, wherein the coil is configured in a sinusoidal pattern.

24. The linear deposition source of claim 23, wherein the sinusoidal pattern of the coil includes. a pitch and wherein a pitch of a portion of the coil positioned at a center portion of the wall is smaller than a pitch of the other portion of the coil.

25. The linear deposition source of claim 23, wherein the sinusoidal pattern of the coil includes a height and wherein a height of a portion of the coil positioned at a center portion of the wall is greater than a height of the other portion of the coil.

26. The linear deposition source of claim 22, wherein the coil is made of metallic material having high melting point and a constant resistance in a longitudinal direction of the coil.

27. A linear deposition source for use in a vapor deposition process, comprising:
a container configured to receive one or more evaporation materials, the container having a pair of side walls formed in a longitudinal direction of the container;
a plate configured to seal an opening of the container and having one or more outlets for discharging the evaporation material; and
a heater coil disposed around the side walls, wherein a first portion of the heater coil extending a first distance in the longitudinal direction along a center portion of the side walls and a second portion of the heater coil extending the first distance in the longitudinal direction along an outer portion of the side walls, wherein the first portion of the heater coil has a first length and the second portion of the heater coil has a second length less than the first length.

28. The linear deposition source of claim 27, wherein the heater coil is configured in a sinusoidal pattern.

29. The linear deposition source of claim 27, wherein the heater coil is configured in a zigzag pattern.

30. The linear deposition source of claim 27, wherein the heater coil includes a geometric pattern having a pitch and wherein a pitch of a portion of the heater coil positioned at a center portion of the side walls is smaller than a pitch of the other portion of the heater coil.

31. The linear deposition source of claim 27, wherein the heater coil includes a geometric pattern having a height and wherein a height of a portion of the heater coil positioned at a center portion of the side walls is greater than a height of the other portion of the heater coil.

32. The linear deposition source of claim 27, wherein the heater coil is made of metallic material having high melting point and a constant resistance in a longitudinal direction of the coil.

33. The linear deposition source of claim 27, wherein the outlets of the top plate include apertures arranged in a row on the top plate.

34. The linear deposition source of claim 27, wherein the outlets of the top plate include nozzles configured to control a rate of flow, speed, direction, mass, and/or pressure of the evaporation material.

35. The linear deposition source of claim 27, wherein the outlets of the top plate include a linear slit for discharging the evaporation material.

36. A linear deposition source for use in a vapor deposition process, comprising:
a container configured to receive one or more evaporation materials, the container having a pair of side walls formed in a longitudinal direction of the container, a pair of end walls, and a bottom wall; and
a heater disposed around the side walls and end walls of the container,
wherein the container defines a volume having three substantially equal sections, one of the sections being adjacent to a center portion of the side walls and the other sections being adjacent to the end walls, wherein the heater is configured to provide approximately same heat energy to each of the sections.

37. The linear deposition source of claim 36, wherein the heater includes a coil of a geometric pattern having a pitch and wherein a pitch of a portion of the coil positioned at a center portion of the side walls is smaller than a pitch of the other portion of the coil.

38. The linear deposition source of claim 36, wherein the heater includes a coil of a geometric pattern having a height and wherein a height of a portion of the coil positioned at a center portion of the side walls is greater than a height of the other portion of the coil.

39. The linear deposition source of claim 36, wherein a resistance of a portion of the coil positioned at a center portion of the side walls is greater than a resistance of the other portion of the coil.

40. A linear deposition source for use in a vapor deposition process, comprising:
a containing means for receiving an evaporation material, the containing means having at least one wall formed in a longitudinal direction of the containing means;
a heating means disposed around the wall of the containing means, wherein a first portion of the heating means extending a first distance in the longitudinal direction along a center portion of the wall and a second portion of the heating means extending the first distance in the longitudinal direction along an outer portion of the wall wherein the first portion of the heating means is configured to generate more heat energy than the second portion of the heating means.

41. The linear deposition source of claim 40, wherein the heating means includes a coil of a geometric pattern having a pitch and wherein a pitch of a portion of the coil positioned at a center portion of the wall is smaller than a pitch of the other portion of the coil.

42. The linear deposition source of claim 40, wherein the heating means includes a coil of a geometric pattern having a height and wherein a height of a portion of the coil positioned at a center portion of the wall is greater than a height of the other portion of the coil.

43. The linear deposition source of claim 40, wherein the heating means includes a coil and wherein a resistance of a portion of the coil positioned at a center portion of the side walls is greater than a resistance of the other portion of the coil.

44. A method for performing a vapor deposition process using a linear deposition source, wherein the linear deposition source includes a container having at least one wall formed in a longitudinal direction of the container and a heater disposed around the wall of the container, comprising:
loading an evaporation material to be deposited on a substrate into the container; and
heating the material in the container to vaporize the material by generating heat energy from the heater,
wherein a first portion of the heater extending a first distance in the longitudinal direction along a center portion of the wall and a second portion of the heater extending the first distance in the longitudinal direction along an outer portion of the wall wherein the first portion of the heater is configured to generate more heat energy than the second portion of the heater.

45. The method of claim 44, wherein the heater includes a coil of a geometric pattern having a pitch and wherein a pitch of a portion of the coil positioned at a center portion of the wall is smaller than a pitch of the other portion of the coil.

46. The method of claim 44, wherein the heater includes a coil of a geometric pattern having a height and wherein a height of a portion of the coil positioned at a center portion of the wall is greater than a height of the other portion of the coil.

47. The method of claim 44, wherein the heater includes a coil and wherein a resistance of a portion of the coil positioned at a center portion of the side walls is greater than a resistance of the other portion of the coil.

48. The method of claim 44, wherein the method is used in PVD processes for manufacturing a display device.
